(19) United States
(12) Patent Application Publication
(10) Pub. No.: US 2005/0136650 A1
(43) Pub. Date: Jun. 23, 2005

(54) Method of manufacturing semiconductor integrated circuit

(75) Inventor: Mayumi Tsuchida, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/010,424

(22) Filed: Dec. 14, 2004

(30) Foreign Application Priority Data
Dec. 18, 2003 (JP) P2003-420478

(51) Int. Cl. H01L 21/4763

(52) U.S. Cl. 438/637; 438/643

(57) ABSTRACT

A method of manufacturing a semiconductor integrated circuit comprising a step of forming a lower-layer wiring, a step of forming a first viahole at a first cross point at which the lower-layer wiring and an upper-layer wiring intersect with each other in a plurality of cross points of a viahole-formation mask and forming a second viahole at a second cross point at which the lower-layer and the upper-layer wirings do not intersect with each other in the plurality of cross points in a state in which a metal wiring mask corresponding to the lower-layer wiring, a metal wiring mask corresponding to the upper-layer wiring and the viahole-formation mask having the plurality of cross points are overlaid on one another, a step of forming a first via which is connected to the lower-layer wiring in the first viahole and forming a second via which is not connected to the lower-layer wiring in the second viahole, and a step of forming the upper-layer wiring in a state in which the upper-layer wiring is connected to the first via and covering the second via with an insulation layer.

### BACKGROUND OF THE INVENTION

1. Field of the Invention

The present invention relates to a method of manufacturing a semiconductor integrated circuit.

2. Description of the Related Art

A semiconductor process of a back-end part in a conventional method of manufacturing a semiconductor integrated circuit is described referring to FIG. 4. In the present example, an exclusive wiring mask and an exclusive viahole-formation mask are used. FIGS. 4A-4D are plan views used for describing a developed product A-a in a product class A of a semiconductor. FIGS. 4E-4H are plan views for describing another developed product A-b in the product class A of the same semiconductor as in FIGS. 4A-4D.

FIG. 4A illustrates a metal wiring mask Ma1 of an Nth layer of the developed product A-a. In the mask Ma1, a pattern Pa1 for a metal wiring Ha1 is formed.

FIG. 4B illustrates a metal wiring mask Ma2 of a (N+1) th layer of the same developed product A-a. In the mask Ma2, a pattern Pa2 for a metal wiring Ha2 is formed.

FIG. 4C illustrates a viahole-formation mask Ma3 exclusively used for the developed product A-a. In the mask Ma3, a pattern Pa3 for a viahole VHa is formed.

As shown in FIG. 4D, where the viahole pattern Pa3 is present on the mask Ma3 and a cross point of the metal wiring Ha1 of the Nth layer and the metal wiring Ha2 of the (N+1)th layer is also present, the viahole VHa is formed in terms of the process.

FIG. 4E illustrates a metal wiring mask Mb1 of the Nth layer of another developed product A-b. In the mask Mb1, a pattern Pb1 for a metal wiring Hb1 is formed.

FIG. 4F illustrates a metal wiring mask Mb2 of the (N+1) th layer of the same developed product A-b. In the mask Mb2, a pattern Pb2 for a metal wiring Hb2 is formed.

FIG. 4G illustrates a viahole-formation mask Mb3 exclusively used for the developed product A-b. In the Mb3, a pattern Pb3 for a viahole VHb is formed.

As shown in FIG. 4H, where the viahole pattern Pb3 is present on the mask Mb3 and a cross point of the metal wiring Hb1 of the Nth layer and the metal wiring Hb2 of the (N+1)th layer is also present, the viahole VHb is formed in terms of the process.

In other words, according to the conventional technology, the developed products A-a and A-b, though they belong to the same product class A, respectively require the different viahole-formation masks Ma3 and Mb3.

Further, a technology pursuing the reduction of the viahole-formation masks Ma3 and Mb3 offered such a constitution that a second metal wiring layer and a first protection film are previously formed on a diffusion-layer formation part (front-end part) and an exclusive viahole-formation mask is thereafter added so as to achieve a desired circuit (No. 11-297698 of the Publication of the Unexamined Japanese Patent Applications).

In the foregoing conventional technology, it is necessary to provide a viahole-formation mask suitable for each different developed product and therefore accurately grasp how the developed product and the viahole-formation mask correspond to each other, which makes the management of the viahole-formation masks more difficult as any product class has more developed products.

Another problem in the semiconductor process is a significantly large amount of cost generated by the increasing number of the required viahole-formation masks along with the increasing number of the layers.

Further, as shown in FIG. 5, a conventional viahole-formation mask Mc3 includes, as viahole patterns, an independent pattern pc3, a pattern Pc4 in a crowded state, a pattern Pc5 having a different pattern ratio and the like in a mixed manner, which generates a pattern dependency. Because of the problem, it becomes difficult in terms of the process to manufacture the semiconductor integrated circuits with a same finishing state.

### SUMMARY OF THE INVENTION

A method of manufacturing a semiconductor integrated circuit according to the present invention is premised on a method of manufacturing a semiconductor integrated circuit having a multi-layer structure, wherein a lower-layer wiring is formed, a viahole for connecting the lower-layer wiring and an upper-layer wiring to each other is formed by means of a viahole-formation mask, a via is formed in the viahole, and the upper-layer wiring is then formed being connected to the via. In addition to the foregoing constitution, a viahole-formation mask, which can be commonly used for developed products of a plurality of types, is prepared as a viahole-formation mask. Using the shared viahole-formation mask, the viahole is formed at a cross point of the lower-layer wiring and the upper-layer wiring and where other than the cross point. The viahole is a through hole, which is a hole where a conductive body (metal) is not embedded. The via constitutes a part formed by embedding the conductive body in the viahole, and can be called the embedding via.

Of the formed vias, any via which does not positionally correspond to the cross point of the lower-layer wiring and the upper-layer wiring is covered with an insulation layer so as to form the upper-layer wiring in the state where the non-corresponding via is isolated.

The foregoing method of manufacturing the semiconductor integrated circuit can be represented in different terms as follows. The method of manufacturing the semiconductor integrated circuit according to the present invention is premised on a method of manufacturing a semiconductor integrated circuit having a multi-layer structure, wherein the following steps are repeated for a plurality of layers in a structure in the middle of the process including a semiconductor substrate and an active element formed thereon: a lower-layer wiring is formed; a first inter-layer insulation film is formed on the lower-layer wiring; a viahole is formed with respect to the first inter-layer insulation film by means of a viahole-formation mask; a via is formed in the viahole; a second inter-layer insulation film is formed on the first inter-layer insulation film and the via; an upper-layer wiring is formed in the second inter-layer insulation film; and the lower-layer wiring and the upper-layer wiring are connected through the via. In addition to the foregoing constitution, using the viahole-formation mask, which can be commonly used for the developed products of the plurality of types, as the viahole formation mask, the viahole is formed at the cross point of the lower-layer wiring and the upper-layer wiring and where other than the cross point. Of the formed vias, any via which does not positionally correspond to the cross point of the lower-layer wiring and the upper-layer wiring is covered with the insulation layer so as to form the upper-layer wiring in the state where the non-corresponding via is isolated.

In the shared viahole-formation mask, viahole patterns are formed so as to correspond to viahole positions of a union of the viahole positions in the developed products of the plurality of types. More specifically, a set of the viahole patterns in the shared viahole-formation mask cover the respective viahole positions of all of the applicable developed products.

When the shared viahole-formation mask is applied to a developed product of a certain type, a plurality of viahole patterns in the mask are divided into those corresponding to an effective via in the relevant developed product and those corresponding to an ineffective dummy via. Further, when the foregoing mask is applied a developed product of another type, the plurality of viahole patterns in the mask are divided into those corresponding to an effective via in the relevant developed product and those corresponding to an ineffective dummy via. How many of the plurality of viahole patterns are effective or ineffective differs based on the type of the developed product.

The via is also formed by means of the ineffective viahole pattern, however, the via does not serve to connect the lower-layer wiring and the upper-layer wiring. More specifically, of the plurality of vias, some do not positionally correspond to the cross-point of the lower-layer wiring and the upper-layer wiring in the relevant developed product, which are the ineffective vias, in other words, dummy vias.

Therefore, when the upper-layer wiring is formed, the dummy via is covered with the insulation layer so as to remain isolated during the formation of the upper-layer wiring.

In the foregoing manner, the via-formation mask is shared by the plurality of developed products. To use the shared viahole-formation via leads to a reduction in the number of the masks, and consequently to a cost reduction.

In the foregoing constitution, a mask in which a plurality of viahole patterns is evenly disposed is preferably used as the shared viahole-formation mask. The even disposition of the viahole patterns can expand a range of the types of the applicable developed products meaning that, in other words, the versatility can be expanded. Further, the process can be facilitated.

Further, referring to the insulation layer for isolating the via in the foregoing constitution, it is preferable that a lower side of the via be covered with the inter-layer insulation film and an upper side thereof be covered with a cap layer.

The invention relating to the method of manufacturing the semiconductor integrated circuit can be developed into an invention relating to the shared viahole-formation mask as, a viahole-formation mask which is provided with a viahole pattern for connecting a lower-layer wiring and an upper-layer wiring and can be commonly used for developed products of a plurality of types, wherein the viahole pattern is formed at a cross point of the lower-layer wiring and the upper-layer wiring and where other than the cross point.

When the shared viahole-formation mask is used, as described, the number of the required masks can be reduced in manufacturing the developed products of the plurality of types, thereby achieving the reduction of the mask-related cost (total mask cost).

In the foregoing shared viahole-formation mask, the plurality of patterns is preferably evenly disposed. The presence of the evenly-disposed viahole patterns leads to a wider range of the types of the applicable developed products and the expansion of the versatility. Further, the process can be facilitated in any of lithography, dry etching, embedding and chemical mechanical polishing (CMP).

Describing the foregoing invention in terms of the semiconductor integrated circuit, a semiconductor integrated circuit according to the present invention comprises a semiconductor substrate and an active element formed on the semiconductor substrate, wherein structure, in which a lower-layer wiring and an upper-layer wiring are connected through a via, is repeated for a plurality of layers, the via is disposed at a cross point of the lower-layer wiring and the upper-layer wiring and where other than the cross point, and the via which does not positionally correspond to the cross point is connected to one of the lower-layer wiring and the upper-layer wiring, or neither of the lower-layer wiring nor the upper-layer wiring remaining isolated.

In the foregoing constitution, the vias are preferably evenly disposed.

### BRIEF DESCRIPTION OF THE DRAWINGS

The present invention is illustrated be way of example and not limitation in the figures of the accompanying drawings, in which like references indicate similar elements and in which:

FIGS. 1A-1G respectively relate to a method of manufacturing a semiconductor integrated circuit according to a preferred embodiment of the present invention, wherein FIGS. 1A-1D are illustrations used for describing a back-end part of a developed product A-a in a product class A of a semiconductor, and FIGS. 1E-1G are illustrations used for describing a back-end part of a developed product A-b, and:

FIG. 1A is a plan view of a metal wiring mask of a lower-layer wiring;

FIG. 1B a plan view of a metal wiring mask of an upper-layer wiring;

FIG. 1C is a plan view of a viahole-formation mask.

FIG. 1D is a plan view of the masks of FIGS. 1A, 1B and 1C overlaid on one another;

FIG. 1E is a plan view of a metal wiring mask of a lower-layer wiring;

FIG. 1F is a plan view of a metal wiring mask of an upper-layer wiring; and

FIG. 1G is a plan view of the masks of FIGS. 1E, 1C and 1F overlaid on one another.

FIGS. 2A-2L are respectively sectional views used for describing a process flow of the back-end part in the method of manufacturing the semiconductor integrated circuit according to the preferred embodiment, wherein:

FIG. 2A is a sectional view illustrating a step of forming the lower-layer wiring in a structure in the process;

FIG. 2B is a sectional view illustrating a step of forming a SiN cap layer and an inter-layer insulation film;

FIG. 2C is a sectional view illustrating a step of forming a resist on the inter-layer insulation film and removing the formed resist;

FIG. 2D is a sectional view illustrating a step of selectively removing the inter-layer insulation film;

FIG. 2E is a sectional view illustrating a step of removing the exposed SiN cap layer;

FIG. 2F is a sectional view illustrating a step of forming a barrier metal;

FIG. 2G is a sectional view illustrating a step of forming a Cu seed layer;

FIG. 2H is a sectional view illustrating a step of forming a Cu part;

FIG. 2I is a sectional view illustrating a step of forming a via by polishing the Cu part;

FIG. 2J is a sectional view illustrating a step of forming the SiN cap layer, inter-layer insulation film and resist;

FIG. 2K is a sectional view illustrating a step of forming a wiring opening; and

FIG. 2L is a sectional view illustrating a step of forming an upper-layer wiring.

FIGS. 3A-3H are respectively sectional views of a mask and the like of a back-end part in a method of manufacturing a semiconductor integrated circuit according to a conventional technology, wherein:

FIG. 3A is a sectional view corresponding to FIG. 2A;

FIG. 3B is a sectional view corresponding to FIG. 2B;

FIG. 3C is a sectional view corresponding to FIG. 2C;

FIG. 3D is a sectional view corresponding to FIG. 2D;

FIG. 3E is a sectional view corresponding to FIG. 2E;

FIG. 3F is a sectional view corresponding to FIG. 2F;

FIG. 3G is a sectional view corresponding to FIG. 2G;

FIG. 3H is a sectional view corresponding to FIG. 2H;

FIG. 3I is a sectional view corresponding to FIG. 21;

FIG. 3J is a sectional view corresponding to FIG. 2J;

FIG. 3K is a sectional view corresponding to FIG. 2K; and

FIG. 3L is a sectional view corresponding to FIG. 2L.

FIGS. 4A-4H are respectively sectional views for describing a back-end part of a developed product A-a in a product class A of a semiconductor in the method of manufacturing the semiconductor integrated circuit according to the conventional technology, wherein:

FIG. 4A is a plan view corresponding to FIG. 1A;

FIG. 4B is a plan view corresponding to FIG. 1B;

FIG. 4C is a plan view corresponding to FIG. 1C;

FIG. 4D is a plan view corresponding to FIG. 1D;

FIG. 4E is a plan view corresponding to FIG. 1E;

FIG. 4F is a plan view corresponding to FIG. 1F;

FIG. 4G is a plan view corresponding to FIG. 1C; and

FIG. 4H is a plan view corresponding to FIG. 1G.

FIG. 5 is a plan view of an exclusive viahole-formation mask.

### DETAILED DESCRIPTION OF THE PREFERRED EMBODIMENT

Hereinafter, a method of manufacturing a semiconductor integrated circuit according to a preferred embodiment of the present invention is described referring to the drawings.

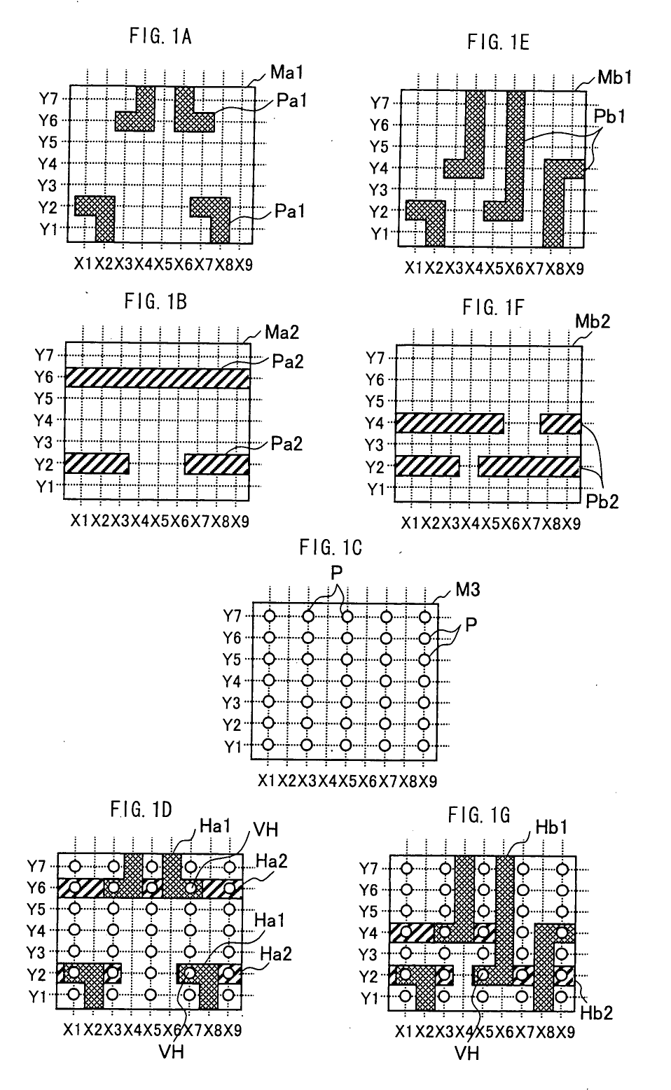

FIGS. 1A-G illustrate process flows used for describing the method of manufacturing the semiconductor integrated circuit according to the preferred embodiment. FIGS. 1A-1D are plan views used for describing a back-end part of a developed product A-a in a product class A of a semiconductor. FIGS. 1E-1G are plan views used for describing a back-end part of another developed product A-b in the same product class A of the semiconductor. FIGS. 1A-1G are sectioned therein by a plurality of vertical reference lines Xn (X1, X2, X3 . . . ) and a plurality of horizontal reference lines Yn (Y1, Y2, Y3 . . . ). FIG. 1C is common for the two process flows.

FIG. 1A illustrates a metal wiring mask Ma1 of an Nth layer of the developed product A-a.

In the metal wiring mask Ma1, a pattern Pa1 for a metal wiring Ha1 is formed. FIG. 1B illustrates a metal wiring mask Ma2 of a (N+1) th layer of the same developed product A-a as shown in FIG. 1A. In the metal wiring mask Ma2, a pattern Pa2 for a metal wiring Ha2 is formed. Regions respectively represented by the patterns Pa1 and Pa2, which are shown in FIGS. 1A and 1B, are both light transmitting parts made of a material having an optical transmission property or opening parts opening through the mask surface. Any part other than the regions where the patterns Pa1 and Pa2 are formed is incapable of the optical transmission.

FIG. 1C illustrates a shared viahole-formation mask M3 applicable to all of the developed products of a plurality of types in the product class A. In FIG. 1C, a pattern p for forming a viahole VH is present at each of cross points where the plurality of vertical reference lines Xn and the plurality of horizontal reference lines Yn intersect with one another. The patterns pare evenly disposed in both vertical and horizontal directions on the mask M3. The vertical evenness and the horizontal evenness can be identical or different to each other.

As shown in FIG. 1D, the viahole VH is formed in terms of the process where the pattern P is present on the shared mask M3. The viahole VH is formed, not only at a cross point of the metal wiring Ha1 of the Nth layer and the metal wiring Ha2 of the (N+1) layer, but also where other than the cross point.

FIG. 1E illustrates a metal wiring mask Mb1 of the Nth layer of the another developed product A-b. In the metal wiring mask Mb1, a pattern Pb1 for a metal wiring Hb1 is formed.

FIG. 1F illustrates a metal wiring mask Mb2 of the (N+1) layer of the same developed product A-b. In the metal wiring mask Mb2, a pattern Pb2 for a metal wiring Hb2 is formed. The patterns Pb1 and Pb2 are formed from light transmitting parts or opening parts.

The shared mask M3 shown in FIG. 1C is applicable, not only to the developed product A-a, but also the developed product A-b and other developed products.

As shown in FIG. 1G, the vaihole VH is formed in terms of the process where the pattern P for forming the viahole VH is present on the shared mask M3. The viahole VH is formed, not only at a cross point of the metal wiring Hb1 of the Nth layer and the metal wiring Hb2 of the (N+1) layer, but also where other than the cross point.

As shown in FIGS. 1D and 1G, the via hole VH is formed at every cross point made by the plurality of vertical reference lines Xn and the plurality of horizontal reference lines Yn. The viaholes VH are, however, isolated at any cross point except for the cross points of the metal wirings Ha1 and Ha2 and the metal wirings Hb1 and Hb2. They exist as a result of the formation step, while having no effectiveness as dummies.

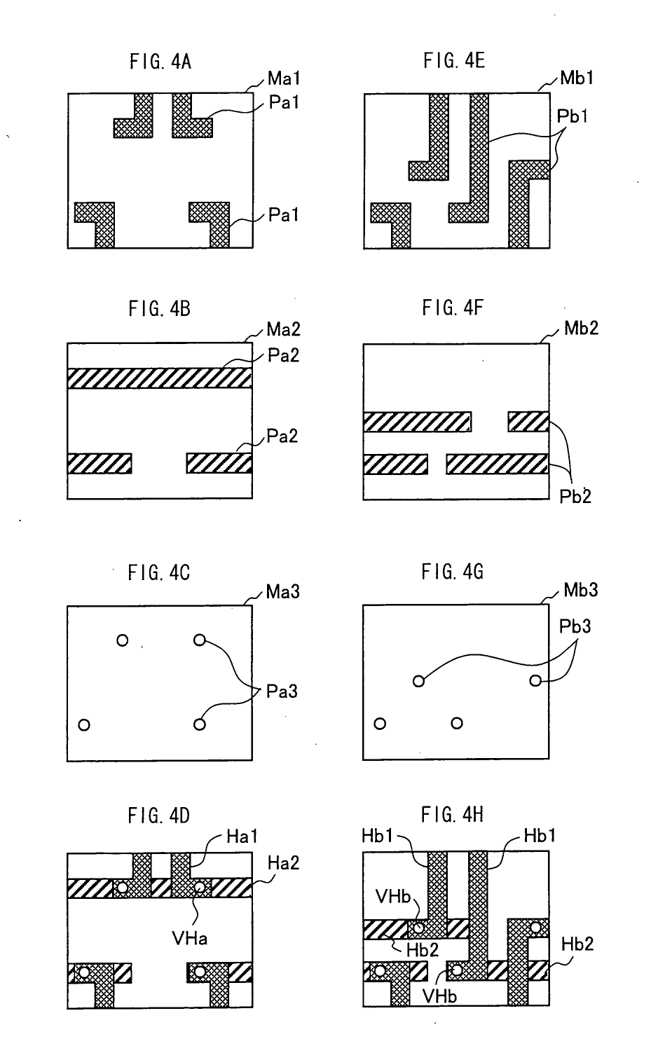

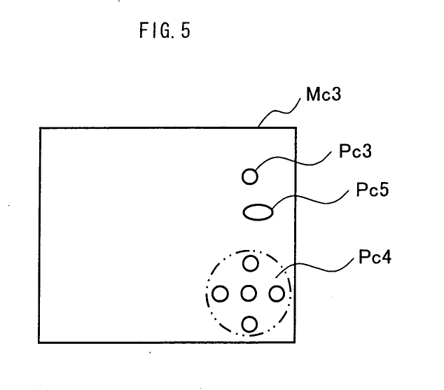

A conventional technology, as shown in FIGS. 4C and 4G, required as many viahole-formation masks as the types of the developed products. In contrast, the present embodiment requires only one shared mask M3, across an entire surface of which the patterns are evenly and scatteringly disposed, for the developed products of the plurality of types because any unnecessary viahole VH of the viaholes VH formed across the entire surface is formed so as to be nullified.

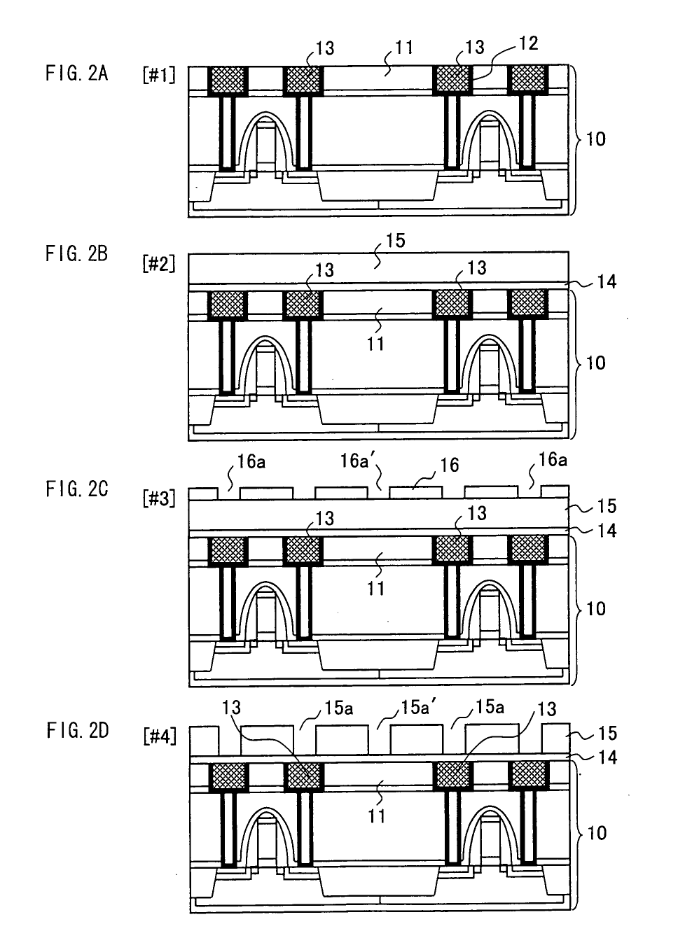

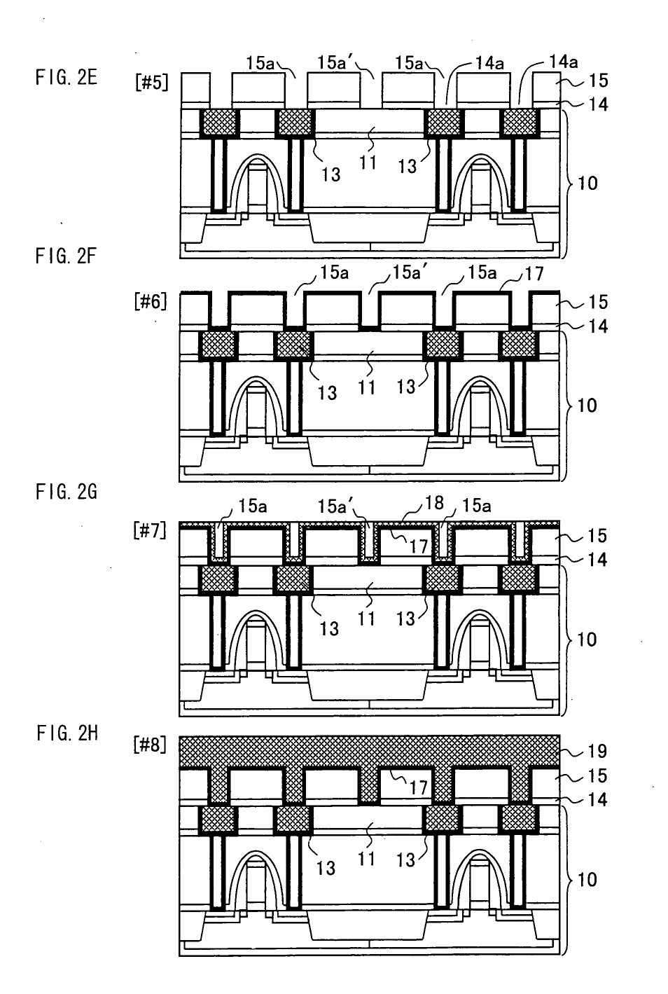

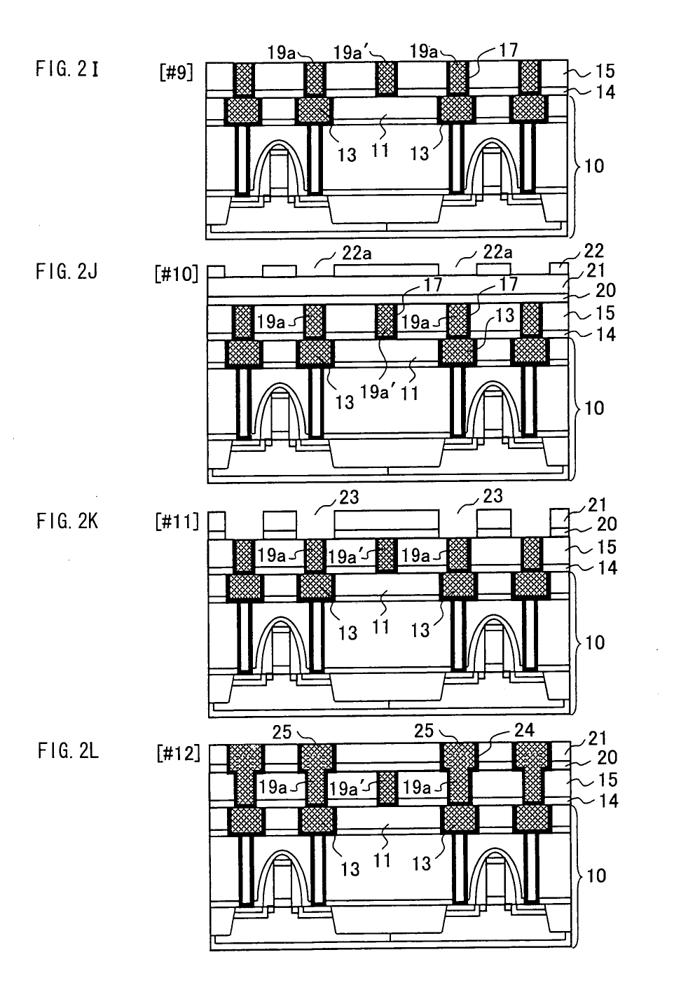

Next is described the process of the back-end part according to the present embodiment including the step of evenly forming the viaholes VH across the entire surface of the mask in the manner that any unnecessary viahole VH is nullified. Here, a flow of the formation of a second-layer wiring in the back-end (Cu wiring process) part in a Cu damascene process is described referring to FIGS. 2A-2L. FIGS. 2A-2L illustrate the successive flow, stages of which are respectively provided with serial numbers #1-#12.

[#1] FIG. 2A is a sectional view when the formation of a first-layer wiring 13, which is a lower-layer wiring, is completed. Referring to reference symbols in FIG. 2A, 10 denotes a structure in the middle of the process in which a MOS transistor of an active element is formed on a semiconductor substrate, 11 denotes an inter-layer insulation film in an uppermost layer of the structure 10 in the middle of the process, 12 denotes a barrier metal formed at an opening part of the inter-layer insulation film 11 and 13 denotes a Cu first-layer wiring embedded in the barrier metal 12. It is assumed here that the metal wiring mask Ma1 is used for the formation of the first-layer wiring 13. At this point of time, a surface of the first-layer wiring 13 remains exposed, which requires the prevention of Cu diffusion.

[#2] As shown in FIG. 2B, a SiN cap (for protection of the first-layer wiring) layer 14 is formed across an entire surface of the uppermost layer, by which the first-layer wiring 13 is completely sealed in. Next, an inter-layer insulation film 15 equivalent to a depth (length) of the viahole is formed across an entire surface of the SiN cap layer 14.

[#3] Next, as shown in FIG. 2C, an entire surface of the inter-layer insulation film 15 is coated with a resist 16. Then, a viahole pattern opening 16a is formed by means of photolithography using the shared mask M3. The openings 16a are formed at an even pitch. The openings 16a positionally correspond to the first-layer wiring 13, however they are necessarily evenly disposed. Therefore, there is a viahole pattern opening 16a′ where the first-layer wiring 13 is absent.

[#4] Subsequent to the formation of the openings 16a and 16a′, as shown in FIG. 2D, a viahole 15a is formed in the inter-layer insulation film 15 by means of dry etching, and the resist 16 is removed. However, the SiN cap layer 14 for protecting the first-layer wiring 13 remains a non-etching state bymeans of selective etching. The viahole with the first-layer wiring 13 disposed immediately below is denoted by the reference symbol 15a, and the viahole with no first-layer wiring 13 disposed immediately below is denoted by a reference symbol 15a′.

It is noted here how the SiN layer 14 functions. The SiN cap layer 14 seals in the first-layer wiring 13 and also serves as an etching stopper.

Because the SiN cap layer 14 is an insulation film, the SiN cap layer 14 provided at a bottom of the viahole 15a is needs to be removed in order to conduct the first-layer wiring 13, which is the lower-layer wiring, and a second-layer wiring 25 (not yet formed at this stage; see FIG. 2L), which is the upper-layer wiring disposed at an upper position of the first-layer wiring 13.

[#5] As shown in FIG. 2E, the SiN cap layer 14 provided at the bottom of the viahole 15a is removed by means of etching. As a result, a damascene structure is formed in the inter-layer insulation film 15. In the etching step, the SiN cap layer 14 provided at a bottom of the viahole 15a′ which is not required for connecting the first-layer wiring 13 and the second-layer wiring 25 is left halfway etched because of the selective etching with respect to the inter-layer insulation film 11 below the Sin cap layer 14.

[#6] Next, as shown in FIG. 2F, a barrier metal 17 made of TiN or TaN is formed inside of the viaholes 15a and 15a′ extending from an upper part of the inter-layer insulation film 15 to an internal part of the damascene structure by means of sputtering. At the time of the formation, the barrier metal 17 is also formed inside of the viahole 15a′ which is not required for connecting the first-layer wiring 13 and the second-layer wiring 25.

How the Cu diffusion is blocked in an upper part of the first-layer wiring 13 in the viahole 15a for connecting the first-layer wiring 13 and the second-layer wiring 25 is described. The Cu diffusion in a central part of the first-layer wiring 13 is blocked by the barrier metal 17. The Cu diffusion in a peripheral part of the first-layer wiring 13 is blocked by the SiN cap layer 14.

[#7] As shown in FIG. 2G, a Cu seed layer 18 for growing Cu by means of electrolytic plating is formed on the barrier metal 17. The growth of Cu is developed using Cu of the Cu seed layer 18 inside of the damascene structure by means of the Cu electrolytic plating, and the grown Cu is embedded in the viaholes 15a and 15a′.

[#8] At that time, a Cu part 19 is concurrently grown on the inter-layer insulation film 15, as shown in FIG. 2H, because the Cu seed layer 18 is also formed on the uppermost inter-layer insulation film 15.

[#9] Next, as shown in FIG. 21, the Cu part 19 grown on the inter-layer insulation film 15, and further, the barrier metal 17 are polished by means of CMP (chemical mechanical polishing) for flattening and the vias 19a and 19a′ are thereby formed. The formed vias 19a and 19a′, except for uppermost surfaces thereof, are entirely blocked by the barrier metal 17 at peripheries and bottoms thereof. The via with the first-layer wiring 13 disposed immediately below is denoted by 19a, and the via with no first-layer wiring 13 disposed immediately below is denoted by 19a′.

Next, the formation (Cu embedding formation method) of a Cu second-layer wiring (M2) is described.

[#10] First, as shown in FIG. 2J, a SiN cap layer 20 is formed across entire surfaces of the vias 19a and 19a′ in order to prevent the Cu diffusion thereof. The vias 19a and 19a′ are thereby completely sealed in. Next, an inter-layer insulation film 21 equivalent to a thickness of the second-layer wiring is formed on the SiN cap layer 20 across an entire surface thereof.

Next, an entire surface of the inter-layer insulation film 21 is coated with a resist 22. Then, a wiring pattern opening 22a is formed by means of the photolithography using the metal wiring mask Ma2. The wiring pattern opening 22a is formed limited to any part where the second-layer wiring 25 is to be formed.

[#11] Next, as shown in FIG. 2K, a wiring opening 23 is formed in the inter-layer insulation film 21 and the SiN cap layer 20 by means of the dry etching, and the resist 22 is removed. The wiring opening 23, though formed at an upper part of the vial 9a, is not formed at an upper part of the vial 9a′. Therefore, the via 19a′ with no first-layer wiring 13 disposed below is not provided with the wiring opening 23 thereon, thereby remaining covered with the SiN cap layer 20 and the inter-layer insulation film 21. The via 19a′, therefore, remains isolated.

[#12] Next, though not shown in the drawing, a barrier metal 24 made of TiN or TaN is formed in the wiring opening 23 by means of the sputtering. Again, the Cu seed layer for growing Cu by means of the electrolytic plating is formed on the barrier metal 24. The growth of Cu is developed using Cu of the seed layer inside of the damascene structure by means of the Cu electrolytic plating, and the grown Cu is embedded as the second-layer wiring 25. At that time, because the seed layer is also formed on the uppermost inter-layer insulation film 21, Cu is also grown therein. Any excessive Cu grown on the inter-layer insulation film 21, and further, the barrier metal 24 are polished by means of the CMP, as a result of which, as shown in FIG. 2L, the flattening and the formation of the second-layer wiring 25 are completed. The formed second-layer wiring 25, except for an uppermost surface thereof, is blocked by the barrier metal 24.

The SiN cap layer 20 serves to block the via 19a′. At the upper part of the via 19a′ which is not required for connecting the first-layer wiring 13 and the second-layer wiring 25 are disposed the SiN cap layer 20 and the inter-layer insulation film 21. Therefore, the via 19a′ is left isolated.

The Cu multi-layer wiring is finalized by returning to the initial state, which corresponds to FIG. 2A, to thereby repeat the same process in the formation of the second-layer wiring (formation of the damascene structure).

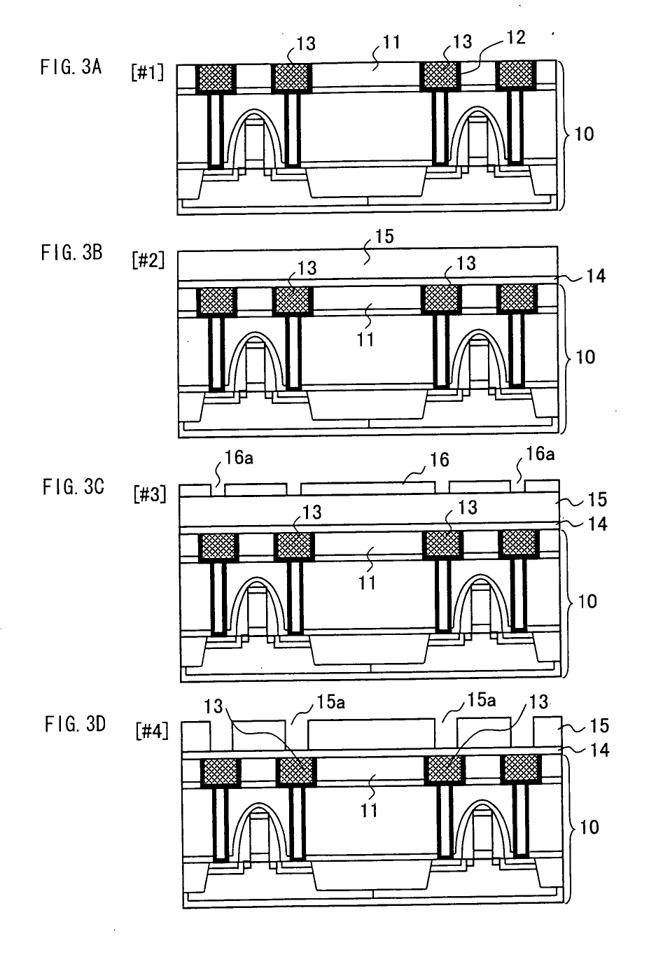

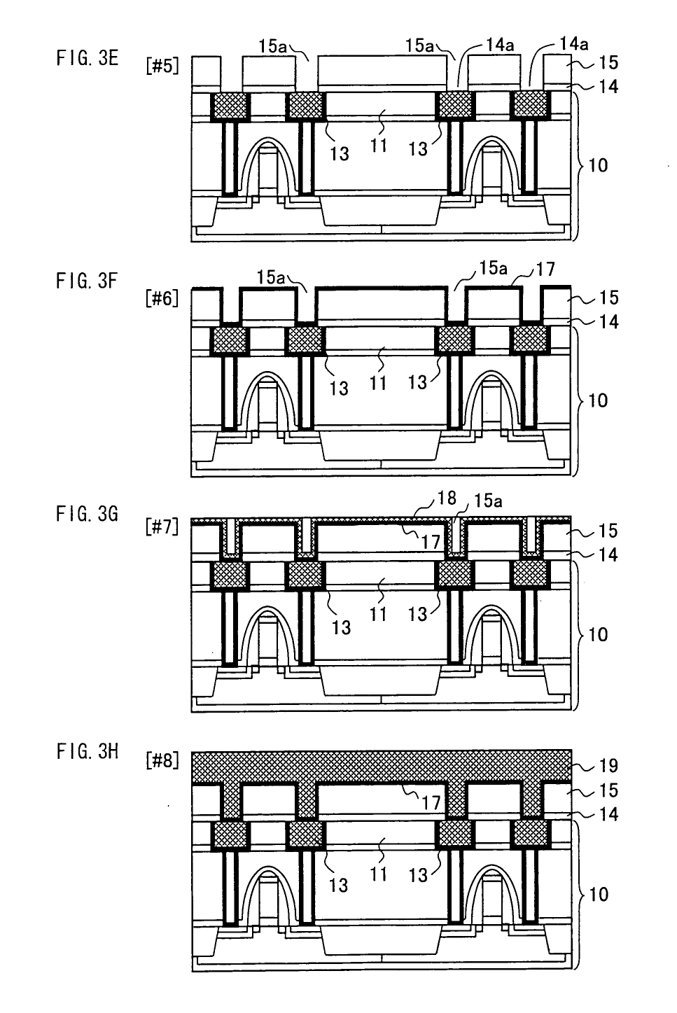

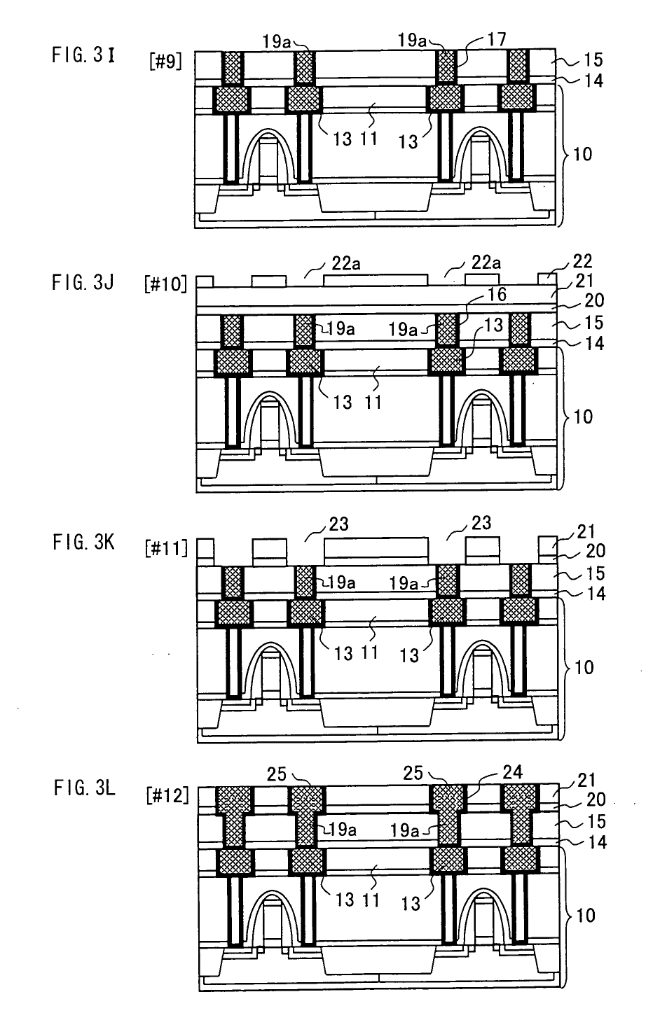

The process flow of the back-end part in the method of manufacturing the semiconductor integrated circuit according to the present embodiment was thus far described referring to FIGS. 2A-2L. For comparison, FIGS. 3A-3L (sectional views) are provided, in which a process flow of the back-end part according to the conventional technology is described. Any identical component between the conventional technology and the present invention is provided with the same reference symbol.

According to the described present embodiment, the viahole-formation patterns are evenly disposed in the shared viahole-formation mask, however, the present invention is not necessarily limited to such an arrangement. The viahole-formation mask of an uneven pattern disposition is acceptable as far as the mask is applicable to the developed products of the plurality of types.

In the present embodiment, the Cu damascene wiring process was described, however, the aluminum wiring and Cu damascene wiring (both in single/dual structures) are both realizable in terms of the process.

For reference, the shared viahole-formation mask shown in FIG. 1, when rotated through 90 degrees or shifted in either right or left direction, can be adopted to the upper-layer wiring.

While the invention has been described and illustrated in detail, it is to be clearly understood that this is intended be way of illustration and example only and is not to be taken by way of limitation, the spirit and scope of this invention being limited only be the terms of the following claims.

1. A method of manufacturing a semiconductor integrated circuit comprising:
a first step of forming a lower-layer wiring;
a second step of forming a first viahole at a first cross point at which the lower-layer wiring and an upper-layer wiring intersect with each other in a plurality of cross points of a viahole-formation mask and forming a second viahole at a second cross point at which the lower-layer and the upper-layer wirings do not intersect with each other in the plurality of cross points in a state in which a metal wiring mask corresponding to the lower-layer wiring, a metal wiring mask corresponding to the upper-layer wiring and the viahole-formation mask having the plurality of cross points are overlaid on one another;
a third step of forming a first via which is connected to the lower-layer wiring in the first viahole and forming a second via which is not connected to the lower-layer wiring in the second viahole; and
a fourth step of forming the upper-layer wiring in a state in which the upper-layer wiring is connected to the first via and covering the second via with an insulation layer.

2. A method of manufacturing a semiconductor integrated circuit as claimed in claim 1, wherein
the lower-layer wiring is formed in a structure in the middle of a process including a semiconductor substrate and an active element formed on the semiconductor substrate, a protection layer is formed on the structure in the middle of the process, an inter-layer insulation film is formed on the protection layer, the inter-layer insulation film is coated with a resist, the coating resist is selectively removed so as to form viahole pattern openings corresponding to the cross points, and the protection layer exposed from the openings is removed so as to form the viaholes in the second step.

3. A method of manufacturing a semiconductor integrated circuit as claimed in claim 2, wherein
a barrier metal is formed inside of the viaholes and a metal seed layer is formed on the barrier metal in the second step.

4. A method of manufacturing a semiconductor integrated circuit as claimed in claim 3, wherein
metal is grown using the metal seed layer and the grown metal is embedded inside of the viaholes so as to form the vias in the third step.

5. A method of manufacturing a semiconductor integrated circuit as claimed in claim 4, wherein the metal is Cu.

6. A method of manufacturing a semiconductor integrated circuit as claimed in claim 1, wherein
patterns corresponding to the cross points in the viahole-formation mask are evenly disposed in vertical and horizontal directions.

7. A method of manufacturing a semiconductor integrated circuit, wherein
a first step of forming a lower-layer wiring in a structure in the middle of a process including a semiconductor substrate and an active element formed on the semiconductor substrate;
a second step of forming a first inter-layer insulation film on the lower-layer wiring after the first step;
a third step of forming a viahole using a viahole-formation mask in the first inter-layer insulation film after the second step;
a fourth step of forming a via in the viahole after the third step;
a fifth step of forming a second inter-layer insulation film on the first inter-layer insulation film and the via after the fourth step; and
a sixth step of forming an upper-layer wiring in the second inter-layer insulation film after the fifth step, are repeated for a plurality of layers,
the viahole is formed at a cross point of the lower-layer wiring and the upper-layer wiring and where other than the cross point using a shared viahole-formation mask which can be commonly used for developed products of a plurality of layers or a plurality of types in a same product class as the viahole-formation mask in the third step, and
any via of the formed vias which does not positionally correspond to the cross point of the lower-layer wiring and the upper-layer wiring is covered with an insulation layer at a lower part and an upper part thereof to thereby generate a state in which the non-corresponding via is not connected to the lower-layer wiring or the upper-layer wiring or both of the lower-layer wiring and the upper-layer wiring.

8. A method of manufacturing a semiconductor integrated circuit, wherein
a first step of forming a lower-layer wiring in a structure in the middle of a process including a semiconductor substrate and an active element formed on the semiconductor substrate;
a second step of forming a first inter-layer insulation film on the lower-layer wiring after the first step;
a third step of forming a viahole using a viahole-formation mask in the first inter-layer insulation film after the second step;
a fourth step of forming a second inter-layer insulation film on the first inter-layer insulation film and the via after the third step; and
a fifth step of forming an upper-layer wiring in the second inter-layer insulation film and the via after the fourth step, are repeated for a plurality of layers,
the viahole is formed at a cross point of the lower-layer wiring and the upper-layer wiring and where other than the cross point using a shared viahole-formation mask which can be commonly used for developed products of a plurality of layers or a plurality of types in a same product class as the viahole-formation mask in the third step, and
any via of the formed vias which does not positionally correspond to the cross point of the lower-layer wiring and the upper-layer wiring is covered with an insulation layer at a lower part and an upper part thereof to thereby generate a state in which the non-corresponding via is not connected to the lower-layer wiring or the upper-layer wiring or both of the lower-layer wiring and the upper-layer wiring.

9. A method of manufacturing a semiconductor integrated circuit as claimed in claim 7, wherein
a mask in which a plurality of viahole patterns are evenly disposed is used as the shared viahole-formation mask in the third step.

10. A method of manufacturing a semiconductor integrated circuit as claimed in claim 7, wherein
as the insulation layer for generating the state in which the via is not connected to the lower-layer wiring or the upper-layer wiring or both of the lower-layer wiring and the upper-layer wiring, a lower side of the via is covered with an inter-layer insulation film and an upper side of the via is covered with a protection layer in the fifth step.

11. a viahole-formation mask which is provided with a viahole pattern for connecting a lower-layer wiring and an upper-layer wiring, wherein
the mask can be commonly used for developed products of a plurality of types,
the viahole pattern is formed at a cross point of the lower-layer wiring and the upper-layer wiring and where other than the cross point.

12. A viahole-formation mask as claimed in claim 11, wherein
the plurality of patterns is preferably evenly disposed.

13. A semiconductor integrated circuit, comprising,
a semiconductor substrate, and
an active element formed on the semiconductor substrate,
wherein a structure, in which a lower-layer wiring and an upper-layer wiring are connected through a via, is repeated into multiple layers, the via is disposed at a cross point of the lower-layer wiring and the upper-layer wiring and where other than the cross point, and the via which does not positionally correspond to the cross point is connected to one of the lower-layer wiring and the upper-layer wiring, or neither of the lower-layer wiring nor the upper-layer wiring remaining isolated.
